(19) United States
(12) Patent Application Publication
(10) Pub. No.: US 2023/0082785 A1
(43) Pub. Date: Mar. 16, 2023

(54) MANUFACTURING PROCESS OF ELECTRONIC DEVICE

(71) Applicant: HERMES-EPITEK CORPORATION, Taipei City (TW)

(72) Inventors: Cheng-Huang Kuo, Tainan City (TW); Kung-Hsuan Lin, Hsinchu County (TW); Yu-Lun Chang, Taichung City (TW)

(73) Assignee: HERMES-EPITEK CORPORATION, Taipei City (TW)

(21) Appl. No.: 17/744,764

(22) Filed: May 16, 2022

(30) Foreign Application Priority Data
Sep. 16, 2021 (TW) 110134606

(51) Int. Cl. H01L 21/02

(52) U.S. Cl. CPC H01L 21/02

(57) ABSTRACT

A manufacturing process of an electronic device including the following steps is provided: placing a reaction part in a pre-reaction chamber; performing a pre-reaction process on the reaction part placed in the pre-reaction chamber; after performing the pre-reaction, transferring the reaction part from the pre-reaction chamber to a reaction chamber; placing a process device in the reaction chamber with the reaction part placed therein; and performing a reaction process on the process device placed in the reaction chamber.

### CROSS-REFERENCE TO RELATED APPLICATION

This application claims the priority benefit of Taiwanese application no. 110134606, filed on Sep. 16, 2021. The entirety of the above-mentioned patent application is hereby incorporated by reference herein and made a part of this specification.

### BACKGROUND

### Technical Field

The disclosure relates to a manufacturing process of devices, and in particular to a manufacturing process of electronic devices.

### Description of Related Art

In the semiconductor manufacturing process, the process device will need to be placed in the chamber of the apparatus to perform corresponding reactions. The chamber generally has parts corresponding to the reactions. In order to make the environment in the chamber have a good atmosphere when performing reaction on the process device, typically the parts in the chamber are subjected to pre-reaction first.

### SUMMARY

The disclosure provides an electronic device manufacturing process, which allows for a higher efficiency in the manufacturing process of the electronic device or the utilization of the corresponding apparatus.

A manufacturing process of an electronic device of the disclosure includes the following steps: placing a reaction part in a pre-reaction chamber; performing a pre-reaction process on the reaction part placed in the pre-reaction chamber; after performing the pre-reaction, transferring the reaction part from the pre-reaction chamber to a reaction chamber; placing a first process device in the reaction chamber with the reaction part placed therein; and performing a first reaction process on the first process device placed in the reaction chamber.

In an embodiment of the disclosure, the electronic device manufacturing process further includes the following steps: after performing the first process reaction, taking the first process device out of the reaction chamber with the reaction part placed therein; after taking the first process device out of the reaction chamber, placing the second process device in the reaction chamber with the reaction part placed therein; and performing a second process reaction on the second process device placed in the reaction chamber.

In an embodiment of the disclosure, the first process reaction and the second process reaction are the same reaction.

In an embodiment of the disclosure, between the step of taking the first process device out of the reaction chamber and the step of placing the second process device in the reaction chamber, the reaction part is not taken out of the reaction chamber.

In an embodiment of the disclosure, the reaction part placed in the reaction chamber constitutes a reaction space.

In an embodiment of the disclosure, the number of reaction parts is multiple, and the multiple reaction parts constitute a reaction space.

In an embodiment of the disclosure, in the step of placing the first process device in the reaction chamber, the first process device is placed in the reaction space formed by the reaction part.

In an embodiment of the disclosure, the electronic device manufacturing process further includes the following steps: after performing the first process reaction, taking the first process device out of the reaction chamber with the reaction part placed therein; and taking the reaction part out of the reaction chamber after taking the first process device out of the reaction chamber.

In an embodiment of the disclosure, the electronic device manufacturing process further includes the following steps: after the step of taking the reaction part out of the reaction chamber or before placing the reaction part in the pre-reaction chamber, performing preventive maintenance on the reaction part.

In an embodiment of the disclosure, the electronic device manufacturing process further includes the following steps: after taking the first process device out of the reaction chamber, placing the second process device in a reaction chamber with a reaction part placed therein; performing the second process reaction on the second process device placed in the reaction chamber; and after performing the second process reaction, taking the second process device out of the reaction chamber with the reaction part placed therein, and the step of taking the reaction part out of the reaction chamber is further performed after the step of taking the second process device out of the reaction chamber.

Based on the above, the electronic device manufacturing process of the disclosure allows for a higher efficiency in the manufacturing process of the electronic device or allows for a higher efficiency for the utilization of the corresponding apparatus.

### BRIEF DESCRIPTION OF THE DRAWINGS

FIG. 1 is a schematic partial flowchart of a manufacturing method of an electronic device according to an embodiment of the disclosure.

FIG. 2 is a schematic partial top view of an apparatus for manufacturing an electronic device according to an embodiment of the disclosure.

FIG. 3 is a schematic partial side perspective view of an apparatus for manufacturing an electronic device according to an embodiment of the disclosure when the apparatus is used for manufacturing an electronic device.

FIG. 4 is a schematic partial side perspective view of an apparatus for manufacturing an electronic device according to an embodiment of the disclosure when the apparatus is used for manufacturing an electronic device.

FIG. 5 is a schematic partial side perspective view of an apparatus for manufacturing an electronic device according to an embodiment of the disclosure when the apparatus is used for manufacturing an electronic device.

FIG. 6 is a schematic partial side perspective view of an apparatus for manufacturing an electronic device according to an embodiment of the disclosure when the apparatus is used for manufacturing an electronic device.

### DESCRIPTION OF THE EMBODIMENTS

The concept of the disclosure can be embodied in different forms and should not be construed as limited to the exemplary embodiments presented herein. That is to say, the description of the embodiments and the corresponding schematic illustrations are intended to illustrate the concept of the disclosure as clear as possible, but are not used to limit the disclosure to the specific form disclosed. Therefore, the concept of the disclosure will involve all modifications, equivalents and alternatives falling within the spirit and scope of the concept of the disclosure.

Throughout the specification and various drawings, the same reference symbol may represent the same element, device, component, object, or the like. In the drawings, in order to make the concept of the disclosure clear, part of the size may be enlarged or reduced. In the drawings, the shape shown can be modified as desired according to manufacturing technology and/or tolerances. Therefore, the exemplary embodiments should not be construed as being limited to the specific shape of the illustrated area.

Unless there is a special purpose or a specific description, the quantitative description are only for exemplifying the embodiments, and are not intended to limit the concept of the disclosure. For example, unless there is a special purpose or special description, the singular form of “one” may refer to plurality in terms of technical concept.

It should be understood that terms such as “first” or “second” are used to describe different elements, but these elements should not be limited by these terms. These terms are only used to distinguish elements from each other. For example, the first element may be referred to as the second element. Similarly, the second element may be referred to as the first element without departing from the scope of the concept of the disclosure.

Unless there is a special purpose or specific description, when an exemplary embodiment can be implemented differently, the specific manufacturing process can be performed in a different order from the order described herein. For example, two processes described in sequence may substantially be performed simultaneously, or may be performed in a reverse order.

Unless there are special purposes or specific description, all terms (including technical terms and scientific terms) have the same meanings commonly understood by those with ordinary knowledge in the technical field to which the disclosure belongs. It should also be understood that the terms (such as those defined in commonly used dictionaries) should be interpreted as having meaning consistent with the meaning comprehended in the relevant technical context, and should not be interpreted in an idealized or overly formal sense, unless specifically defined as such.

In the manufacturing process of electronic products, the shape, thickness, pattern or size of objects (such as intermediates in the manufacturing process) may be changed. The above-mentioned changes can be reasonably understood by those with ordinary knowledge in the technical field to which the disclosure belongs. Therefore, no further description is incorporated in the specific and drawings.

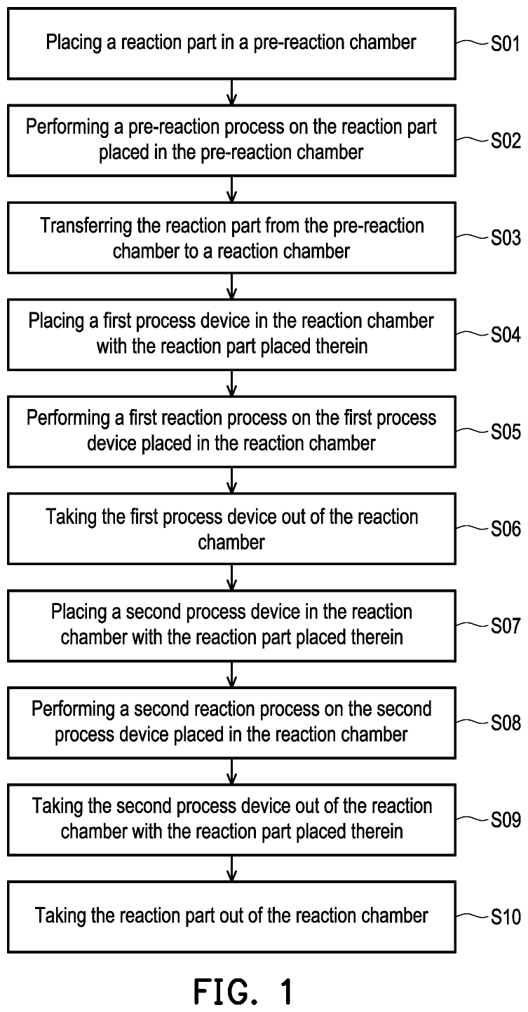

Please refer to FIG. 1, the manufacturing process of an electronic device includes at least the following steps. Step S01: The reaction part is placed in the pre-reaction chamber. Step S02: Pre-reaction is performed on the reaction part placed in the pre-reaction chamber. Step S03: After performing the pre-reaction (as described in step S02), the reaction part is transferred from the pre-reaction chamber to the reaction chamber. Step SO4: The first process device is placed in the reaction chamber with the reaction part placed therein. Step S05: The first process reaction is performed on the first process device placed in the reaction chamber.

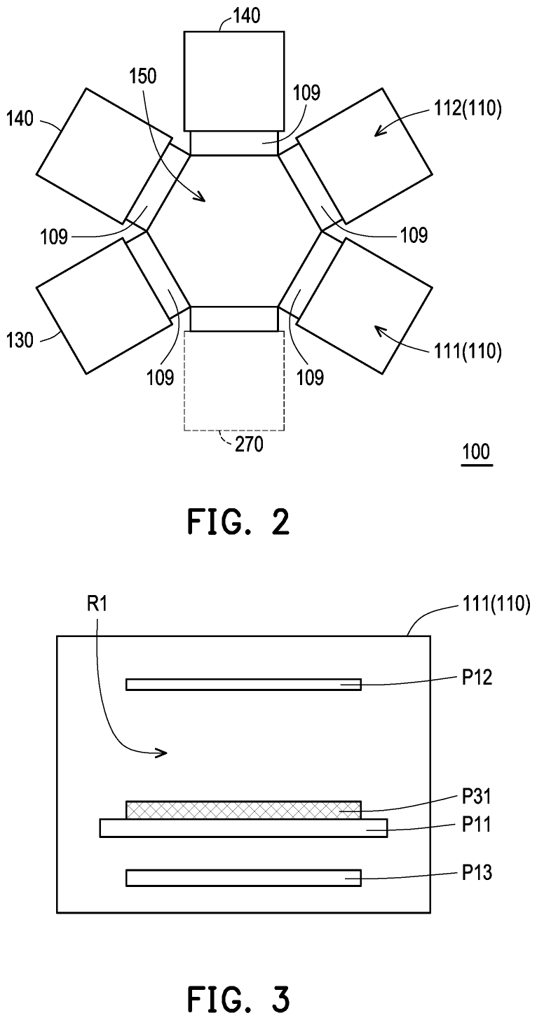

In order to explain the manufacturing process of the electronic device more clearly, an example of an apparatus will be used for description in the following description. However, it should be noted that the apparatus that can be used to manufacture the electronic device or the apparatus that can perform the electronic device manufacturing process is not limited to the apparatus 100 in the following description. For example, the apparatus 100 in FIG. 2 may be referred to as a cluster tool, for example. In an embodiment not shown, the manufacturing process of the electronic device of the disclosure can also be applied to a stand-alone reactor.

Please refer to FIG. 2, the apparatus 100 may include a plurality of chambers. The space for one chamber and the other chamber can be divided by appropriate components (such as gate 109). For example, the apparatus 100 may include multiple reaction chambers (e.g., one or more pre-reaction chambers 110 and/or one or more reaction chambers 130). Appropriate equipment can be connected to the reaction chamber through appropriate pipes or lines to perform appropriate processes or reactions in the reaction chamber. For example, gas equipment (such as gas inlet equipment and/or gas exhaust equipment) can be connected to the reaction chamber through a suitable gas pipeline to fill the reaction chamber with appropriate gas and/or exhaust the gas in the reaction chamber. For example, liquid equipment (such as liquid feeding equipment and/or liquid draining equipment) can be connected to the reaction chamber through a suitable liquid pipeline to inject appropriate liquid into the reaction chamber and/or to drain the liquid out of the reaction chamber. For example, the power supply equipment can be connected to a device in the reaction chamber (such as a heater, a plasma generator, a light-emitting device, a motor, or other appropriate device) through an appropriate power line, so as to be adapted for adjusting the space in the reaction chamber (for example, the reaction space described later) to an appropriate atmosphere. In addition, the pipelines or lines can be controlled through corresponding valves, gates, switches or detectors, the disclosure provides no limitation thereto.

In an embodiment, the apparatus 100 may include other chambers 140. Other chambers 140 may include a heating chamber, a cooling chamber, a queuing chamber, a load-lock chamber that is adapted for enabling the process device to be transferred in from the outside (for example, a FOUP (Front Opening Unified Pod); but not limited thereto) or transferred out, but the disclosure is not limited thereto. The other chambers 140 may also be the same or similar to the pre-reaction chamber 110 or the reaction chamber 130.

In this embodiment, a connecting chamber 150 may be included between the multiple reaction chambers, but the disclosure is not limited thereto. Objects (such as the reaction part P31, reaction part P32, the first process device 271 or the second process device 272 described later, but not limited thereto) can be transported by a transfer mechanism (not shown; such as a robotic arm, a transfer plate/transfer wheel, but not limited thereto) from one chamber (such as a reaction chamber, but not limited thereto) to another chamber (such as another reaction chamber, but not limited thereto) via the connecting chamber 150, but the disclosure is not limited thereto. In an embodiment not shown, the object can be directly transferred from one chamber (such as a reaction chamber, but not limited thereto) to another chamber (such as another reaction chamber, but not limited thereto).

In an embodiment, a carrier/transporting object (such as a FOUP, but not limited thereto) adapted for carrying or transporting a process device at the outside (such as something different from the apparatus 100) can also be directly or indirectly connected to the connecting chamber 150.

Please refer to FIG. 1, FIG. 2 and FIG. 3, a reaction part P31 (process part/process parts) is placed in a pre-reaction chamber 111 (one of the pre-reaction chambers 110). In addition, the reaction part P31 placed in the pre-reaction chamber 111 is subjected to a pre-reaction.

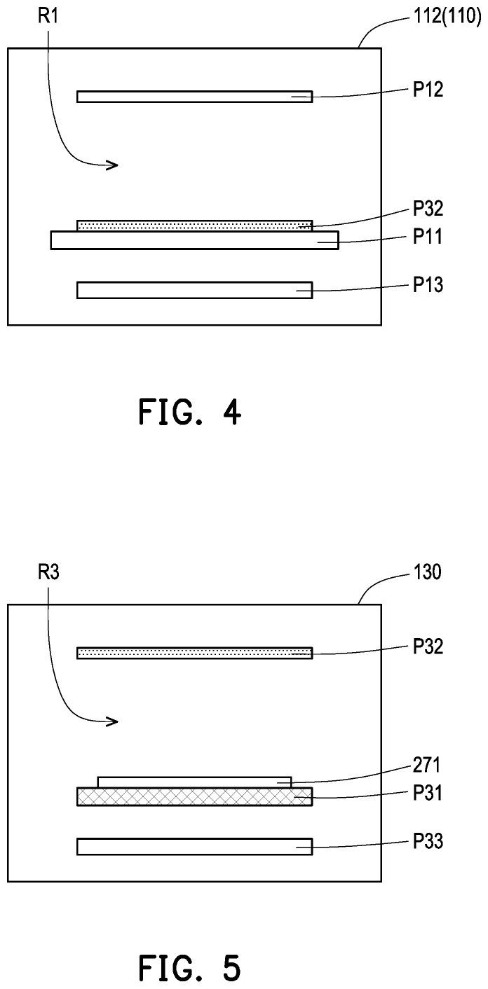

Please refer to FIG. 1, FIG. 2 and FIG. 4, another reaction part P32 is placed in another pre-reaction chamber 112. Moreover, the reaction part P32 placed in the pre-reaction chamber 112 is subjected to a pre-reaction.

In this embodiment, the reaction part P31 and the reaction part P32 may be different components, but the disclosure is not limited thereto. Taking a deposition reaction or an epitaxial reaction as an example, the reaction part P31 may include a susceptor, and/or the reaction part P32 may include a ceiling or an injector.

In an embodiment, the reaction part P31 and/or the reaction part P32 that are subjected pre-reaction may be new parts or good parts after being subjected to preventive maintenance (PM).

In this embodiment, the reaction part P31 and the reaction part P32 can be respectively placed in different pre-reaction chambers 110 (such as pre-reaction chamber 111 and pre-reaction chamber 112) to be subjected to pre-reaction separately, but the disclosure is not limited thereto. In an embodiment, the pre-reaction timing for the reaction part P31 and the reaction part P32 may overlap. In this way, the utilization efficiency of the apparatus 100 may be higher.

In an embodiment, the reaction part P31 may be placed in a pre-reaction chamber (such as one of the pre-reaction chambers 110) to perform a pre-reaction on the reaction part P31 placed in the pre-reaction chamber. Then, after the reaction part P31 is subjected to the pre-reaction, the reaction part P31 is transferred out of the pre-reaction chamber. Only then, the reaction part P32 is placed in the same pre-reaction chamber, and then the reaction part P32 placed in the pre-reaction chamber is subjected to a pre-reaction.

In this embodiment, the device or part in the pre-reaction chamber 110 may be the same or similar to the device or part in the reaction chamber 130 described later. In this way, the environmental atmosphere during the pre-reaction in the pre-reaction chamber 110 can be the same or similar to the environmental atmosphere during the reaction in the reaction chamber 130. For example, the pre-reaction chamber 110 may include corresponding part P11, part P12, and/or device P13. The part P11 can be the same or similar to the reaction part P31. The part P12 can be the same or similar to the reaction part P32. The part P11 and the part P13 can form the corresponding pre-reaction space R1. The part P13 can be the same or similar to the reaction part P33 in the subsequent reaction chamber 130. The part P13 and/or the reaction part P33 may include, but are not limited to, a heater or an induction device.

Please refer to FIG. 1, FIG. 2 and FIG. 5, after performing the pre-reaction on the reaction parts P31 and P32, the reactions part P31 and P32 can be transferred out of the pre-reaction chamber 110, and then transferred to the reaction chamber 130. The reaction parts P31 and P32 can be assembled and/or fixed in an appropriate manner to form a reaction space suitable for the reaction in the reaction chamber 130. According to the corresponding reaction or process, the reaction space can be an open space, a semi-open space, or an enclosed space. Taking FIG. 5 as an example, the reaction part P31 and the reaction part P32 can be arranged oppositely in the reaction chamber 130 to form a semi-open reaction space R3 between them.

Please continue to refer to FIG. 1, FIG. 2 and FIG. 5, the first process device 271 is placed in the reaction chamber 130 with the reactions parts P31 and P32 placed therein. Then, the first process device 271 placed in the reaction chamber 130 is subjected to the first process reaction. For example, a suitable transfer mechanism can be used to place the first process device 271 in the reaction space R3 formed by the reaction parts P31 and P32.

In an embodiment, the process device (e.g., the first process device 271 or the subsequent second process device 272; but not limited thereto) may include a substrate; or, a substrate and a film, layer or device on the substrate. For example, the substrate may include wafers (such as silicon wafers, gallium nitride (GaN) wafers or other suitable wafers), glass or polymer plates, but the disclosure is not limited thereto. In another example, the substrate may have a patterned or unpatterned conductive layer, a patterned or unpatterned insulating layer, a patterned or unpatterned semiconductor layer, or a combination of the foregoing.

In this embodiment, the process reaction (such as the first process reaction or the second process reaction described later) can be adjusted according to requirements, and the disclosure provides no limitation thereto. For example, the process reaction may include, but is not limited to, film-forming reaction or layer-forming reaction (e.g., including but not limited to deposition reaction, epitaxial reaction, plating reaction, coating reaction), removal reaction (e.g., including but not limited to etching reaction, grinding reaction) or common or possible reactions in the manufacturing process of other electronic devices (e.g., including but not limited to semiconductor devices, light-emitting diode devices, electronic packaging devices). Moreover, the pre-reaction may correspond to the process reaction. Taking the deposition reaction as an example, the corresponding pre-reaction may include a pre-deposition reaction. Taking the cleaning reaction as an example, the corresponding pre-reaction may include a pre-clean reaction. Taking cleaning reaction or wet etching as an example, the corresponding pre-reaction may include a pre-clean reaction or a pre-rinse reaction.

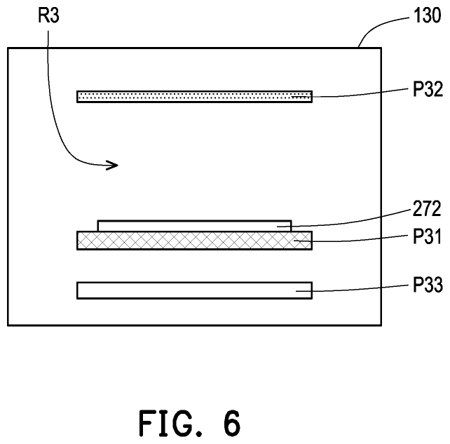

Please continue to refer to FIG. 1, FIG. 2 and FIG. 5 to FIG. 6, after performing the first process reaction on the first process device 271, the first process device 271 can be taken out of the reaction chamber 130 with the reaction parts P31 and P32 placed therein. Then, the second process device 272 is placed in the reaction chamber 130 with the reactions part P31 and P32 placed therein. Thereafter, the second process reaction is performed on the second process device 272 placed in the reaction chamber 130. For example, a suitable transfer mechanism can be used to place the second process device 272 in the reaction space R3 formed by the reaction parts P31 and P32.

In this embodiment, the first process reaction and the second process reaction are the same reaction or homogeneous reaction. For example, the recipe of the first process reaction may be the same or partially the same as the recipe of the second process reaction. In another example, the first process reaction and the second process reaction can be both a film-forming reaction/layer-forming reaction; or, the first process reaction and the second process reaction can be both a removing reaction.

In this embodiment, between the step of taking the first process device 271 out of the reaction chamber 130 and the step of placing the second process device 272 in the reaction chamber 130, the reaction parts P31 and P32 are not taken out of the reaction chamber 130.

In an embodiment, after performing the second process reaction on the second process device 272, the second process device 272 can be taken out of the reaction chamber 130 with the reaction parts P31 and P32 placed therein. Then, the reaction parts P31 and P32 are taken out of the reaction chamber 130. Thereafter, the reaction parts P31 and P32 that are taken out are subjected to preventive maintenance.

In an embodiment, the first process device 271 and/or the second process device 272 taken out of the reaction chamber 130 can be further processed through an appropriate process (such as an appropriate semiconductor process; but not limited thereto) to form a corresponding electronic device. That is to say, the first process device 271 and/or the second process device 272 taken out of the reaction chamber 130 can be regarded as another form of process device. Next, the previously mentioned another form of process device can be formed into a corresponding electronic device through an appropriate process. In an embodiment, the first process device 271 and/or the second process device 272 taken out of the reaction chamber 130 can also be directly regarded as electronic devices.

In summary, in the disclosure, the reaction part can be subjected to pre-reaction in a chamber first, and then transferred to another chamber, and then the process device is placed in another chamber with the reaction part placed therein to perform a corresponding process reaction. In this manner, it is possible to allow for a higher efficiency in the manufacturing process of the electronic device or the utilization of the corresponding apparatus.

What is claimed is:

1. An electronic device manufacturing process, comprising:
placing a reaction part in a pre-reaction chamber;
performing a pre-reaction process on the reaction part placed in the pre-reaction chamber;
after performing the pre-reaction process, transferring the reaction part from the pre-reaction chamber to a reaction chamber;
placing a first process device in the reaction chamber with the reaction part placed therein; and
performing a first reaction process on the first process device placed in the reaction chamber.

2. The electronic device manufacturing process according to claim 1, further comprising:
after performing the first process reaction, taking the first process device out of the reaction chamber with the reaction part placed therein;
after taking the first process device out of the reaction chamber, placing a second process device in the reaction chamber with the reaction part placed therein; and
performing a second process reaction on the second process device placed in the reaction chamber.

3. The electronic device manufacturing process according to claim 2, wherein the first process reaction and the second process reaction are the same reaction.

4. The electronic device manufacturing process according to claim 2, wherein between the step of taking the first process device out of the reaction chamber and the step of placing the second process device in the reaction chamber, the reaction part is not taken out of the reaction chamber.

5. The electronic device manufacturing process according to claim 1, wherein the reaction part placed in the reaction chamber constitutes a reaction space.

6. The electronic device manufacturing process according to claim 5, wherein the number of the reaction parts is multiple, and the multiple reaction parts constitute the reaction space.

7. The electronic device manufacturing process according to claim 5, wherein in the step of placing the first process device in the reaction chamber, the first process device is placed in the reaction space formed by the reaction part.

8. The electronic device manufacturing process according to claim 1, further comprising:
after performing the first process reaction, taking the first process device out of the reaction chamber with the reaction part placed therein; and
taking the reaction part out of the reaction chamber after taking the first process device out of the reaction chamber.

9. The electronic device manufacturing process according to claim 8, further comprising:
after the step of taking the reaction part out of the reaction chamber or before the step of placing the reaction part in the pre-reaction chamber, performing preventive maintenance on the reaction part.

10. The electronic device manufacturing process according to claim 8, further comprising:
after taking the first process device out of the reaction chamber, placing a second process device in the reaction chamber with the reaction part placed therein;
performing a second process reaction on the second process device placed in the reaction chamber; and
after performing the second process reaction, taking the second process device out of the reaction chamber with the reaction part placed therein, wherein:
the step of taking the reaction part out of the reaction chamber is further performed after the step of taking the second process device out of the reaction chamber.
